(19) United States
(12) Patent Application Publication
(10) Pub. No.: US 2005/0067653 A1
(43) Pub. Date: Mar. 31, 2005

(54) Vertical DMOS transistor device, integrated circuit, and fabrication method thereof

(76) Inventors: Andrej Litwin, Danderyd (SE); Jan-Erik Muller, Ottobrunn (DE); Hans Norstrom, Solna (SE)

Correspondence Address: Andreas Grubert;Baker Botts L.L.P., One Shell Plaza, 910 Louisiana, Houston, TX, 77002-4995, US

(21) Appl. No.: 10/941,783

(22) Filed: Sep. 15, 2004

(30) Foreign Application Priority Data
Sep. 30, 2003 (SE) 0302594-7

(51) Int. Cl. H01L 29/76; H01L 21/336

(52) U.S. Cl. 257/335; 438/306; 438/307; 257/336

(57) ABSTRACT

A monolithically integrated vertical DMOS transistor device comprises a semiconductor substrate (11), a gate including a gate semiconductor layer region (27) on top of a gate insulation layer region (25), a source (31), a drain including a buried drain region (13) and a drain contact (21), and a channel region (29) arranged beneath the gate region. The drain comprises a lightly doped, preferably retrograde doped, drain region (23) arranged between the gate and the buried drain region, and the source (31), the channel region (29) and the lightly doped drain region (23) are arranged in a doped well region (17), wherein the lightly doped drain region has a higher doping level than the well region to thereby enhance the high frequency properties of the vertical DMOS transistor device.

### PRIORITY

This application claims priority to Swedish application no. 0302594-7 filed Sep. 30, 2003.

### TECHNICAL FIELD OF THE INVENTION

The present invention generally relates to the field of integrated circuit technology, and more specifically the invention relates to a vertical DMOS (double diffused MOS) transistor device, to an integrated circuit including the DMOS transistor device, and to a fabrication method of the integrated circuit with the DMOS transistor device, respectively.

### DESCRIPTION OF RELATED ART AND BACKGROUND OF THE INVENTION

The ever-increasing market for microwave power amplifiers in PCS, CDMA, and WCDMA systems requires low cost, and ease of use technology that can provide high power and good linearity performance. LDMOS devices started replacing bipolar devices in base station applications three to four years ago and LDMOS has for multiple reasons become the leading technology for base station power amplifier applications. The LDMOS device has high gain and shows excellent back-off linearity. The breakdown voltage BVdss can be easily adjusted by the layout to fit different application voltages.

The integration of LDMOS transistors into an radio frequency BiCMOS process without affecting other devices is disclosed in O. Bengtsson, A. Litwin, and J. Olsson: “Small-Signal and Power Evaluation of Novel BiCMOS-Compatible Short Channel LDMOS Technology”, IEEE Transactions on Microwave Theory and Techniques, Vo. 51, No. 3, March 2003, and in the published U.S. patent application No. 20020055220 A1. This opens a way to low cost and more efficient linear integrated radio frequency power amplifiers with multiple amplification steps on the very same die.

To optimize the high frequency properties of an LDMOS transistor, the drain drift region ought to have a non-conform distribution of doping concentration along the current path, with highest concentration at the drain contact. An example of an advanced method to achieve this goal can be found in T. M. L. Lai et al., “Implementation of linear doping profiles for high voltage thin-film SOI devices”, Proceedings of the 7th International Symposium on Power Semiconductor Devices and ICs, ISPSD '95 (IEEE Cat. No.95CH35785), 1995, pp. 315-20.

In more conventional high frequency LDMOS transistors the drift region is divided in two segments, where the segment closest to the gate region is implanted with the lowest n-type dopant dose.

Further, a vertical DMOS transistor is described in U.S. Pat. No. 5,071,778 issued to Hutter et al.

### SUMMARY OF THE INVENTION

The LDMOS transistor as such occupies a rather large area. Further, the LDMOS transistor optimized for high frequency operation is either difficult to integrate in a standard BiCMOS process or adds significant complexity to the process. Particularly, the optimization of the extended drain region is difficult to perform, which incurs higher costs.

The prior art vertical DMOS transistor is not optimized for high frequency operation. The doping levels of the well region are not suitable for high frequency operation. If the doping levels would be increased in the well region, the parasitic junction capacitances per unit area would be increased.

Accordingly, it is an object of the present invention to provide a vertical DMOS transistor device in an integrated circuit, particularly an integrated circuit for radio frequency applications, which DMOS transistor device overcomes the problems associated with the prior art described above.

Further, it is an object of the invention to provide an integrated circuit comprising such a DMOS transistor device.

Still further, it is an object of the invention to provide a method in the fabrication of an integrated circuit, particularly an integrated circuit for radio frequency applications, including a vertical DMOS transistor, which accomplishes the above object.

These objects can according to the present invention be attained by a monolithically integrated vertical high frequency DMOS transistor device comprising a semiconductor substrate, a gate including a gate semiconductor layer region on top of a gate insulation layer region, a source, a drain including a buried drain region and a drain contact, and a channel region arranged beneath said gate region, wherein said drain comprises a lightly doped drain region arranged between said gate and said buried drain region and said source, said channel region, and said lightly doped drain region are arranged in a doped well region, wherein said lightly doped drain region has a higher doping level than said well region.

The lightly doped drain region can be arranged with distance from said channel region. The lightly doped drain region may have a retrograde doping profile. The lightly doped drain region can be a selectively implanted region. The drain can be n-type doped. The vertical DMOS transistor can be a radio frequency power transistor. The vertical DMOS transistor device can be part of a monolithically integrated circuit. The vertical DMOS transistor device can be part of a monolithically integrated radio frequency circuit.

The object can also be achieved by a method in the fabrication of a monolithically integrated high frequency circuit including a vertical DMOS transistor device comprising the steps of:
providing a semiconductor substrate,
forming a drain for said vertical DMOS transistor device in said substrate, said drain including a buried drain region and a drain contact,
forming a doped well region above said buried drain region,
forming a gate for said vertical DMOS transistor device above said doped well region, said gate including a gate semiconductor layer region on top of a gate insulation layer region,
forming a channel region for said vertical DMOS transistor device in said doped well region,
forming a source for said vertical DMOS transistor device in said doped well region, and
forming a lightly doped drain region in said doped well region on top of said buried drain region and below said gate, wherein said lightly doped drain region is formed with a higher doping level than said doped well region.

The channel region for said vertical DMOS transistor device can be formed with a distance from said lightly doped drain region. The lightly doped drain region can be formed to have a retrograde doping profile. The drain can be n-type doped. The lightly doped drain region can be selectively implanted. The lightly doped drain region can be selectively implanted simultaneously with implantation of a secondary implanted collector for a bipolar transistor. The lightly doped drain region can be selectively implanted simultaneously with implantation of a CMOS well region. The lightly doped drain region can be implanted prior to the step of forming said gate.

By providing a monolithically integrated vertical DMOS transistor comprising a semiconductor substrate, a gate including a gate semiconductor layer region on top of a gate insulation layer region, a source, a drain including a buried drain region and a drain contact, and a channel region arranged beneath the gate region, wherein the drain further comprises a lightly doped drain region, which extends under the DMOS gate from the buried drain region and upwards, and the channel region and the lightly doped drain region are arranged in a doped well region, which has a lower, preferably several times lower, doping level than the lightly doped drain region, a DMOS transistor device with enhanced high frequency properties is obtained.

By lightly doped drain region should be understood that the doping level is lower than that of the buried drain region, but higher than that of a well region, in which the channel region and the lightly doped drain region are located.

Preferably, the lightly doped drain region has a graded, particularly retrograde, doping profile. The vertical DMOS transistor may be fabricated in a BiCMOS or pure CMOS process, where the lightly doped drain region may be formed by means of selective implantation, e.g. simultaneously with implantation of a secondary implanted collector (SIC) for bipolar transistors or simultaneously with implantation of CMOS well regions, or simultaneously with both.

Further characteristics of the invention and advantages thereof will be evident from the detailed description of preferred embodiments of the present invention given hereinafter and the accompanying FIGS. 1-5, which are given by way of illustration only, and thus are not limitative of the present invention.

### BRIEF DESCRIPTION OF THE DRAWINGS

FIG. 1 is a highly enlarged cross-sectional view of a monolithically integrated vertical DMOS transistor device according to a preferred embodiment of the present invention.

FIGS. 2-5 are highly enlarged cross-sectional views of a portion of a semiconductor structure during processing according to a further preferred embodiment of the present invention.

### DETAILED DESCRIPTION OF EMBODIMENTS

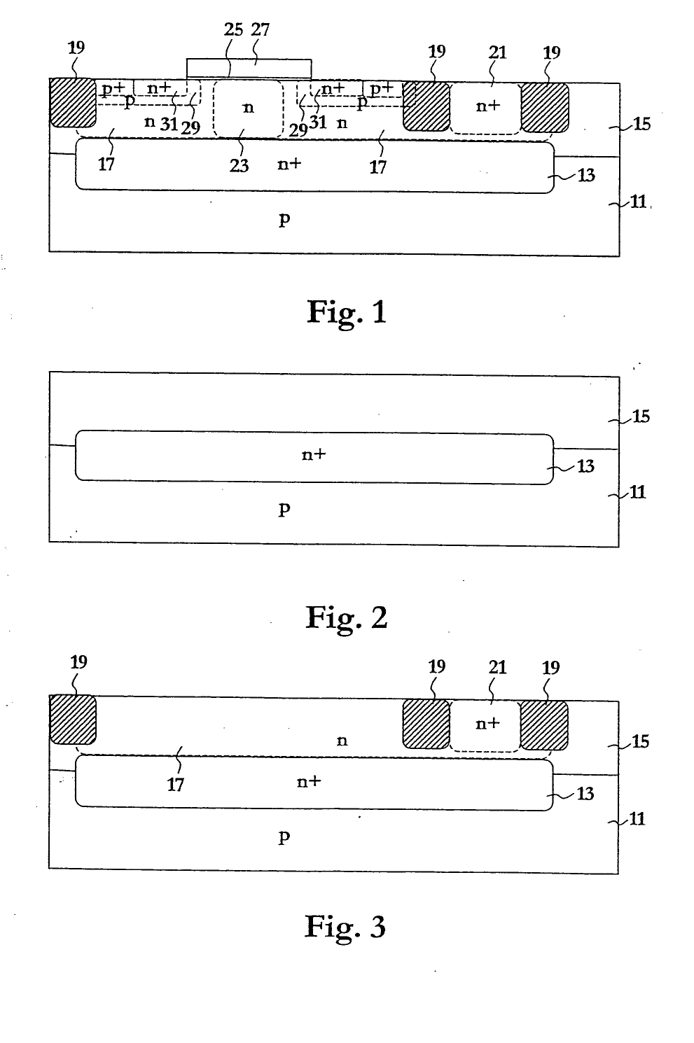

In FIG. 1 is shown, in an enlarged cross-sectional view, a vertical silicon LDMOS transistor device according to a first preferred embodiment of the present invention. The DMOS transistor device, which is particularly adapted for high power radio frequency applications, comprises a p-type doped semiconductor substrate 11, in which an n⁺-type doped buried DMOS drain region 13 is formed. An epitaxial layer 15 is provided on top of the substrate 11, in which an n-type doped well region 17 is formed.

A DMOS gate including a gate polycrystalline silicon layer region 27 on top of a gate oxide layer region 25 is provided on top of the structure and laterally well within the n-type doped well region 17. A p-type doped diffused well region or channel pocket 29 is formed in the n-type doped well region 17 to surround and partly subsist beneath the DMOS gate 25, 27. An n⁺-type doped DMOS source region 31 is formed in the pocket 29 at the edge of the DMOS gate. An n⁺-typed doped DMOS drain contact 21 provides a connection from the surface of the structure down to the n⁺-type doped buried DMOS drain region 13. Insulation areas, such as shallow trench insulation regions 19, provide electrical insulation in a lateral dimension of the DMOS gate/source region 25, 27, 31 and the DMOS drain contact 21 in a conventional manner.

According to the present invention the drain of the vertical DMOS transistor device comprises a lightly n-type doped drain region 23, which extends under the DMOS gate from the n⁺-type doped buried DMOS drain region 13 and upwards. The lightly n-type doped drain region 23 may be arranged laterally separated from the pocket 29 with a certain distance such that the channel length is set by the pocket 29 and the source region 31, and not by lightly n-type doped drain region 23. Alternatively, the lightly n-type doped drain region 23 may overlap the n⁺-type doped DMOS source region 31 to some extent due to side diffusion of the implanted n-type species of the drain region 23. However, this overlap should preferably be kept to a minimum since it increases the parasitic source-drain capacitance.

A purpose of the lightly n-type doped drain region 23 is to provide for a graded doping profile of the drift region of the DMOS drain to enhance the high frequency properties of the DMOS transistor device. Thus, the lightly n-type doped drain region 23 has advantageously a retrograde doping profile.

The lightly n-type doped drain region 23 has a higher doping level than the n-type doped well region 17, which drain region 23 may be doped as an ordinary collector region of a bipolar transistor. Since the region substantially beneath the pocket 29 has a very low n-type doping level, the parasitic source-drain capacitance is minimized.

The vertical DMOS transistor as described above provides a very compact high voltage and high frequency device for use in radio frequency and microwave circuits. The fabrication of the device may be implemented in a deep submicron BiCMOS process with only very little process complexity added. Alternatively, the inventive vertical DMOS transistor is implemented in a radio frequency CMOS process, wherein a few additional process steps have to be added.

Further, the combination of the inventive vertical DMOS transistors with LDMOS power transistors and analog, mixed signal and radio frequency BiCMOS or CMOS devices easily achievable on a single die, leads to an attractive variety of circuit design options otherwise not easily available.

Note that the layout of the transistor device of FIG. 1 provides for a centrally located gate region 25, 27 surrounded at two sides by the source region 31. The DMOS drain contact 21 exists on one side only of the source region 31. Nevertheless, the present invention is not limited to such a design, but is applicable to any kind of vertical DMOS transistor structure.

It shall further be appreciated that while the illustrated preferred embodiment of the vertical DMOS transistor is an n-channel device, the present invention is not limited in this respect. The invention is equally applicable to p-channel devices.

It shall yet further be appreciated that while the present invention is primarily intended for radio frequency power silicon DMOS devices, it may as well be useful for smaller devices in silicon-based integrated radio frequency circuits. Further, the DMOS device of the present invention may be realized in other materials such as e.g. SiC, GaAs, etc.

Below, a preferred embodiment for manufacturing an integrated vertical DMOS transistor device of the present invention is described. The fabrication may be performed in a BiCMOS process or in a pure CMOS process, to which only a few process steps are added. Many of the process steps, e.g. including ion implanting steps for forming wells and source and drain regions, are well known to the person skilled in the art and these steps will therefore not be described at all here, or will only be schematically indicated. The main focus is put on how the drain of the vertical DMOS transistor is formed.

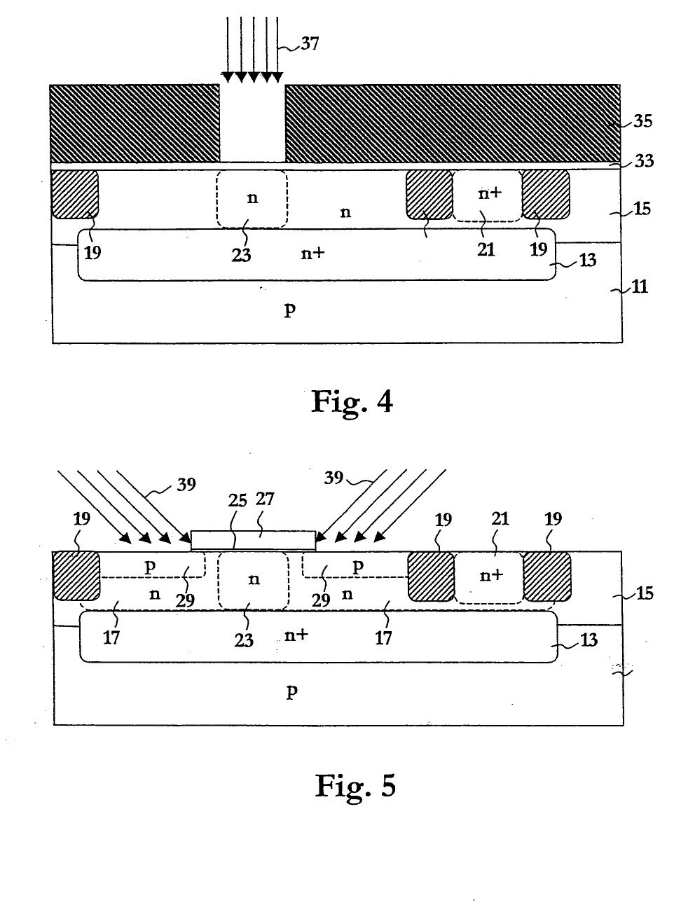

FIG. 2 shows a cross section of a semiconductor structure including a partially processed vertical DMOS transistor. Reference numeral 11 denotes the p-type doped silicon substrate, 13 denotes the buried n⁺-type doped layer region, and 15 denotes the epitaxial silicon layer.

In the epitaxial silicon layer 15 the n-type doped well 17 is formed by means of ion implantation. Shallow trench insulation regions 19 are formed to surround a gate/source area and a drain contact area, respectively. The n⁺-type doped drain contact region 21 is formed in the drain contact area for connection of the buried n⁺-type doped layer region to the surface of the structure. In a BiCMOS or other bipolar process the n⁺-type doped drain contact is formed simultaneously with collector contact plugs for npn bipolar transistors. The resulting structure is illustrated in FIG. 3.

Next, an oxide 33 is formed—deposited or grown—on top of the structure. In FIG. 4 a deposited oxide layer is shown. A photo resist is deposited, patterned and etched to form a mask 35 for implantation of n-type dopants 37 to create the lightly n-type doped drain region 23 with retrograde doping profile. The necessary doping implantation in the drain region 33 will be performed only in the drain current path.

The mask 35 and the oxide 33 are then removed and a gate oxide layer and a gate polycrystalline silicon layer are deposited, patterned and etched to form the gate oxide region 25 and the polycrystalline silicon gate region 27.

Next, the p-type doped well 29 defining the channel length is formed by means of implantation with a p-type dopant 39, preferably inclined at an angle to the normal of the substrate surface as being illustrated in FIG. 5. Thereby, the p-type doped well 29 is created partly underneath the gate region of the vertical DMOS transistor. The ion implantation may be performed through a mask (not illustrated).

The source region 31 is then formed in a conventional manner by means of ion implantation through a mask (not illustrated). The resulting structure is illustrated in FIG. 1. The structure may then be processed in a manner well known in the art.

The selective implantation of the lightly n-type doped drain region 23 may be identical with the implantation of secondary implanted collectors for bipolar transistors in a BiCMOS process or in a bipolar process, or with the implantation of CMOS n-type doped well regions. Alternatively, several implantation steps, e.g. both the above indicated, are used for forming the lightly n-type doped drain region 23 in a BiCMOS process.

By utilizing the above identified selective implantation steps for forming the lightly n-type doped drain region 23, the desired graded doping profile is achieved since both the secondary implanted collector and the CMOS n-type doped well region in a deep sub-micrometer BiCMOS process have so called retrograde doping profile.

References to processes, in which the present invention may be implemented after only small modifications, are found in the article by O. Bengtsson, A. Litwin, and J. Olsson, in the published U.S. patent application No. 20020055220 A1, and in WO 02/091463 A1, the contents of which being hereby incorporated by reference.

If the invention is implemented in an ordinary BiCMOS process only an implantation step to form the channel pocket has to be added to the process. If a BiCMOS process as disclosed in the article by O. Bengtsson, A. Litwin, and J. Olsson is used the invention can be implemented without additional process steps.

If the invention is implemented in a pure CMOS process disclosed in the above identified U.S. patent application the steps of forming the n⁺-type doped buried drain region, forming the n-type doped well region, forming the n⁺-type doped drain contact, and implanting the channel pocket need to be added to the process.

1. A monolithically integrated vertical high frequency DMOS transistor device comprising:
a semiconductor substrate,
a gate including a gate semiconductor layer region on top of a gate insulation layer region,
a source,
a drain including a buried drain region and a drain contact, and
a channel region arranged beneath said gate region, wherein
said drain comprises a lightly doped drain region arranged between said gate and said buried drain region and
said source, said channel region, and said lightly doped drain region are arranged in a doped well region, wherein said lightly doped drain region has a higher doping level than said well region.

2. The vertical DMOS transistor device of claim 1, wherein said lightly doped drain region is arranged with distance from said channel region.

3. The vertical DMOS transistor device of claim 1, wherein said lightly doped drain region has a retrograde doping profile.

4. The vertical DMOS transistor device of claim 1, wherein said lightly doped drain region is a selectively implanted region.

5. The vertical DMOS transistor device of claim 1, wherein said drain is n-type doped.

6. The vertical DMOS transistor device of claim 1, wherein said vertical DMOS transistor is a radio frequency power transistor.

7. A monolithically integrated circuit comprising the vertical DMOS transistor device according to claim 1.

8. A monolithically integrated radio frequency circuit comprising the vertical DMOS transistor device according to claim 1.

9. A method in the fabrication of a monolithically integrated high frequency circuit including a vertical DMOS transistor device comprising the steps of:
providing a semiconductor substrate,
forming a drain for said vertical DMOS transistor device in said substrate, said drain including a buried drain region and a drain contact,
forming a doped well region above said buried drain region,
forming a gate for said vertical DMOS transistor device above said doped well region, said gate including a gate semiconductor layer region on top of a gate insulation layer region,
forming a channel region for said vertical DMOS transistor device in said doped well region,
forming a source for said vertical DMOS transistor device in said doped well region, and
forming a lightly doped drain region in said doped well region on top of said buried drain region and below said gate, wherein said lightly doped drain region is formed with a higher doping level than said doped well region.

10. The method of claim 9, wherein said channel region for said vertical DMOS transistor device is formed with a distance from said lightly doped drain region.

11. The method of claim 9, wherein said lightly doped drain region is formed to have a retrograde doping profile.

12. The method of claim 9, wherein said drain is n-type doped.

13. The method of claim 9, wherein said lightly doped drain region is selectively implanted.

14. The method of claim 13, wherein said lightly doped drain region is selectively implanted simultaneously with implantation of a secondary implanted collector for a bipolar transistor.

15. The method of claim 13, wherein said lightly doped drain region is selectively implanted simultaneously with implantation of a CMOS well region.

16. The method of claim 14, wherein said lightly doped drain region is selectively implanted simultaneously with implantation of a CMOS well region.

17. The method of claim 13, wherein said lightly doped drain region is implanted prior to the step of forming said gate.
